(19) United States
(12) Patent Application Publication
(10) Pub. No.: US 2020/0083393 A1
(43) Pub. Date: Mar. 12, 2020

(54) FLEXIBLE INTEGRATED CONCENTRATORS FOR SOLAR CELLS

(71) Applicant: THE JOHNS HOPKINS UNIVERSITY, Baltimore, MD (US)

(72) Inventors: Susanna M. THON, Baltimore, MD (US); Yida LIN, Baltimore, MD (US); Gary QIAN, Baltimore, MD (US); Garrett UNG, Baltimore, MD (US)

(21) Appl. No.: 16/500,502

(22) PCT Filed: Mar. 30, 2018
(86) PCT No.: PCT/US18/02527

§ 371 Date: Oct. 3, 2019

Related U.S. Application Data
(60) Provisional application No. 62/480,572, filed on Apr. 3, 2017.

(51) Int. Cl. H01L 31/054; H01L 31/0224; H01L 31/0352; H01L 31/0725; H01L 31/073; H01L 31/0749

(52) U.S. Cl. CPC H01L 31/0543; H01L 31/022466; H01L 31/0749; H01L 31/0725; H01L 31/073; H01L 31/035218

(57) ABSTRACT

Disclosed herein are solar cell devices comprising a transparent substrate, a solar cell fabricated over the transparent substrate and a polymeric concentrator comprising a concentrating lens with a planar surface, wherein the concentrating lens is optically aligned with the solar cell such that the concentrating lens provides a uniform illumination over an entire surface of the solar cell. Also, disclosed herein are methods of making solar cell devices and in particular polymeric concentrators.

### RELATED APPLICATIONS

This application claims the benefit of U.S. Provisional Application No. 62/480,572, filed Apr. 3, 2017, the disclosure of which is herein incorporated by reference in its entirety

### FIELD OF THE INVENTION

The present disclosure relates to solar cells, concentrators for thin film solar cells and in particular to flexible solution-processed solar cells with flexible polymeric concentrators.

### BACKGROUND

There has been growing interest in emerging thin film photovoltaic technologies, such as copper zinc tin sulfide (CZTS) solar cells, and derivatives CZTSe and CZTSSe, copper indium gallium selenide (CIGS) solar cells, dye-sensitized solar cells, also known as “Grätzel cells”, organic solar cells, perovskite solar cells, polymer solar cells, and quantum dot solar cells. Among all the emerging technologies, colloidal quantum dots (CQDs) have been studied extensively in recent years and are regarded as a promising candidate due to low cost due to their inexpensive materials, solution processability, short fabrication cycle, mechanical flexibility, scalable manufacturing, and infrared responsivity enabling multijunction, transparent, and colored devices compared with their epitaxially-grown inorganic counterparts. In addition, there has been an increasing interest on fabricating CQD solar cells via solution processing on flexible substrates and patterning and scaling pixels into more complicated shapes and larger sizes for specific applications. However, solution-processability brings several challenges in providing large high-quality pixel sizes. Inhomogeneity of the quantum dot itself, impurities in the starting material solution and introduced during the fabrication process, all contribute to possible charge carrier recombination centers, short-circuit paths, and break-down of the well-defined layered structures, all of which decrease the performance and in some cases, cause device failures. Therefore, pixels are usually made small enough to allow the best possible uniformity within the pixel. For example, nearly all reported high-power conversion efficiency (PCE) PbS CQD devices are measured on pixels of 0.1-0.01 cm², which amount to less than 1 mW output power assuming 10% PCE at one sun, an inarguably small figure for real-life applications. Concentrators have been long implemented on traditional high-efficiency industrial solar cells to further boost the efficiencies. However, current approaches to solar cell concentration use bulky, external optics that are costly to manufacture and configure, or rigid, stationary, and large-scale integrated systems

Hence, there is a need for a new approach for concentrator design for thin film solar cells on flexible substrates.

### BRIEF SUMMARY

The following presents a simplified summary in order to provide a basic understanding of some aspects of one or more embodiments of the present teachings. This summary is not an extensive overview, nor is it intended to identify key or critical elements of the present teachings, nor to delineate the scope of the disclosure. Rather, its primary purpose is merely to present one or more concepts in simplified form as a prelude to the detailed description presented later.

Additional goals and advantages will become more evident in the description of the figures, the detailed description of the disclosure, and the claims.

In an aspect, there is a solar cell device comprising:
a) a transparent substrate;
b) a solar cell fabricated over the transparent substrate; and
c) a polymeric concentrator comprising a concentrating lens with a planar surface, wherein the concentrating lens is optically aligned with the solar cell such that the concentrating lens provides a uniform illumination over an entire surface of the solar cell.

In an embodiment of the solar cell device, the transparent substrate comprises a first surface and a second surface, the second surface being opposite the first surface, and wherein the solar cell comprises a first electrode disposed over the first surface of the transparent substrate and an active layer disposed in between and in contact with the first electrode and a second electrode.

In another embodiment, the transparent substrate is disposed in between and in contact with the first electrode of the solar cell and the planar surface of the polymeric concentrator, such that the concentrating lens provides a uniform illumination through the transparent substrate over an entire surface of the solar cell.

In yet another embodiment, the solar cell is disposed in between and in contact with the transparent substrate and the planar surface of the polymeric concentrator, such that the concentrating lens provides a uniform illumination through the second electrode over an entire surface of the solar cell.

In one embodiment, the solar cell is a solution-processed solar cell.

In another embodiment, the solar cell comprises one or more of a perovskite solar cell; an organic solar cell; a colloidal quantum dot solar cell; a crystalline, multicrystalline, or polycrystalline semiconductor-based cell; an amorphous silicon-based cell; a dye-sensitized solar cell; a CZTS/Se solar cell; a CIGS solar cell; or a hybrid thereof.

In an embodiment, the active layer comprises one or more of colloidal quantum dots (CQD), organic electronic materials, perovskites, dye sensitized porous material, or a mixture thereof.

In an embodiment of the solar cell, the active layer comprises colloidal quantum dots (CQD).

In another embodiment, the solar cell further comprises an n-type conductive layer disposed in between and in contact the first transparent electrode and the active layer.

In yet another embodiment, the solar cell further comprises a buffer layer disposed in between and in contact with the active layer and the second electrode.

In another embodiment of the solar cell device, the polymeric concentrator comprises a spherical concentrating lens, a conical concentrating lens, an aspherical concentrating lens, or a Fresnel concentrating lens.

In an embodiment, the transparent substrate is a flexible polymeric substrate, or a flexible glass substrate.

In another embodiment, the flexible polymeric substrate comprises a polyester, a polyimide, a polymeric organosilicon compound or a polyamide.

In yet another embodiment, the polymeric concentrator is fabricated using a 3-D printed polymeric lens mold.

In an embodiment, the solar cell device further comprises an array of solar cell pixels and an array of polymeric concentrators, where each concentrating lens of the array of polymeric concentrators is optically aligned with each solar cell pixel of the array of solar cell pixels, such that each concentrator provides a substantial uniform illumination over an entire surface of each solar cell pixel.

In another embodiment, the solar cell is a multi-junction solar cell comprising:
a) a visible junction including a first transparent electrode in contact with the first surface of the transparent substrate; and
b) a recombination layer disposed between and in contact with the visible junction and an infrared junction, wherein the infrared junction comprises a second electrode farthest from the transparent substrate.

In an embodiment of the multi-junction solar cell, the visible junction comprises a perovskite solar cell; an organic solar cell; a colloidal quantum dot solar cell; a crystalline, multicrystalline, or polycrystalline semiconductor-based cell; an amorphous silicon-based cell; a dye-sensitized solar cell; a CZTS/Se solar cell; a CIGS solar cell; or a hybrid thereof; and the infrared solar cell comprises a colloidal quantum dot solar cell or a silicon solar cell; or a hybrid thereof.

In an aspect, there is a method of making a solar cell device comprising:
a) providing a transparent substrate having a first surface and a second surface, the second surface being opposite the first surface;
b) fabricating a solar cell on the first surface of the transparent substrate; and
c) providing a polymeric concentrator comprising a concentrating lens with a planar surface;
d) optically aligning the concentrating lens of the polymeric concentrator with the solar cell, such that the concentrating lens provides a uniform illumination over an entire surface of the solar cell.

In an embodiment of the method of making a solar cell device, the step of optically aligning the concentrating lens of the polymeric concentrator with the solar cell further comprises bonding the planar surface of the polymeric concentrator with the second surface of the transparent substrate, such that the concentrating lens provides a uniform illumination through the transparent substrate over an entire surface of the solar cell.

In another embodiment of the method of making a solar cell device, the step of optically aligning the concentrating lens of the polymeric concentrator with the solar cell further comprises bonding the planar surface of the polymeric concentrator with the second electrode of the solar cell, such that the concentrating lens provides a uniform illumination through the second electrode over an entire surface of the solar cell.

In yet another embodiment, the step of fabricating a solar cell on the first surface of the transparent substrate comprises fabricating a solar cell by solution processing.

In another embodiment, the step of providing a polymeric concentrator comprises:
a) designing a computer-aided lens-mold (lens-mold CAD) by optical modelling to uniformly illuminate the solar cell through the second surface of the substrate;
b) printing a three-dimensional lens mold using the lens-mold CAD by additive manufacturing;
c) slurry polishing the lens-mold to create a smooth surface;
d) pouring a curable composition into the lens-mold; and
e) curing the curable composition to obtain a polymeric concentrator comprising a concentrating lens with a planar surface.

In another embodiment, the curable composition comprises a mixture of a polydimethylsiloxane monomer and a curing agent.

In yet another embodiment, the curable composition comprises polydimethylsiloxane, silicone, epoxy, spin-on-glass (SOG), acrylic, or other moldable, transparent materials.

Further areas of applicability of the present invention will become apparent from the detailed description provided hereinafter. It should be understood that the detailed description and specific examples, while indicating some preferred aspects of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1A schematically illustrates a cross-sectional view of an exemplary solar cell device with illumination through the transparent substrate, in accordance with various embodiments of the present disclosure.

FIG. 1B schematically illustrates a cross-sectional view of an exemplary solar cell device with illumination through the second electrode of the solar cell, in accordance with various embodiments of the present disclosure.

FIG. 2 schematically illustrates a cross-sectional view of another exemplary solar cell device, in accordance with various embodiments of the present disclosure.

FIG. 3 schematic illustrates of a cross-sectional view of an exemplary colloidal quantum dot (CQD) solar cell, in accordance with various embodiments of the present disclosure.

FIG. 4 shows a schematic illustration of a cross-sectional view of an exemplary multi-junction solar cell device, in accordance with various embodiments of the present disclosure.

FIG. 5 shows a computer aided design (CAD) of the lens-mold, in accordance with various embodiments of the present disclosure.

FIG. 6 shows an exemplary aspherical lens design in accordance with various embodiments of the present disclosure.

FIG. 7A shows an image of an exemplary as-is lens-mold made using a 3-D printer, in accordance with various embodiments of the present disclosure.

FIG. 7B shows an image of the exemplary lens-mold shown in FIG. 7A after polishing, in accordance with various embodiments of the present disclosure.

FIG. 8A shows an image of a polished lens array-mold made using a 3-D printer, in accordance with various embodiments of the present disclosure.

FIG. 8B shows an image of an array of concentrators made using the lens array-mold of FIG. 8A, in accordance with various embodiments of the present disclosure.

FIG. 9A shows an image of an exemplary array of lead sulfide colloidal quantum dot (PbS CQD) solar cells with a flexible PDMS concentrator bonded to the second surface of the transparent glass substrate, in accordance with various embodiments of the present disclosure.

FIG. 9B shows an image of an exemplary solar cell device including a flexible PDMS concentrator bonded to the second surface of the transparent glass substrate, in accordance with various embodiments of the present disclosure.

FIG. 10 shows transmission spectrum of PDMS concentrators, in accordance with various embodiments of the present disclosure.

FIG. 11 shows device current as a function of device voltage for a control solar cell with no concentrator, an exemplary solar cell device with spherical half inch diameter lens, and an exemplary solar cell device with conical half inch diameter lens.

FIG. 12 shows short circuit current magnification ratio and power magnification ratio with concentrators, in accordance with various embodiments of the present disclosure, attached as various incident power densities.

FIG. 13 shows solar cell figures of merit plotted as a function of actual incident irradiance at the pixel plane for solar cells without concentrators and with concentrators, in accordance with various embodiments of the present disclosure.

It should be noted that some details of the drawings have been simplified and are drawn to facilitate understanding of the present teachings rather than to maintain strict structural accuracy, detail, and scale.

The drawings above are not necessarily to scale, with emphasis instead generally being placed upon illustrating the principles in the present disclosure. Further, some features may be exaggerated to show details of particular components. These drawings/figures are intended to be explanatory and not restrictive.

### DETAILED DESCRIPTION

The following description of various preferred aspect(s) is merely exemplary in nature and is in no way intended to limit the invention, its application, or uses. Reference will now be made in detail to the various embodiments in the present disclosure. The embodiments are described below to provide a more complete understanding of the components, processes and apparatuses disclosed herein. Any examples given are intended to be illustrative, and not restrictive. Throughout the specification and claims, the following terms take the meanings explicitly associated herein, unless the context clearly dictates otherwise. The phrases “in some embodiments” and “in an embodiment” as used herein do not necessarily refer to the same embodiment(s), though they may. Furthermore, the phrases “in another embodiment” and “in some other embodiments” as used herein do not necessarily refer to a different embodiment, although they may. As described below, various embodiments may be readily combined, without departing from the scope or spirit of the present disclosure.

As used herein, the term “or” is an inclusive operator, and is equivalent to the term “and/or,” unless the context clearly dictates otherwise. The term “based on” is not exclusive and allows for being based on additional factors not described, unless the context clearly dictates otherwise. In the specification, the recitation of “at least one of A, B, and C,” includes embodiments containing A, B, or C, multiple examples of A, B, or C, or combinations of A/B, A/C, B/C, etc. In addition, throughout the specification, the meaning of “a,” “an,” and “the” include plural references. The meaning of “in” includes “in” and “on.”

As used throughout, ranges are used as shorthand for describing each and every value that is within the range. Any value within the range can be selected as the terminus of the range. In addition, all references cited herein are hereby incorporated by reference in their entireties. In the event of a conflict in a definition in the present disclosure and that of a cited reference, the present disclosure controls.

Unless otherwise specified, all percentages and amounts expressed herein and elsewhere in the specification should be understood to refer to percentages by weight. The amounts given are based on the active weight of the material.

As used herein, the term “solar cell device” refers to a device including at least one solar cell with a concentrator. Hence, as used herein, the term “solar cell device” may include a single solar cell with a single concentrator or an array of solar cells with an array of concentrators.

Usually, “top” means “closest to the illumination side” (i.e. closest to the sun) and “bottom” means “farthest from the illumination side.” However, as used herein, “top” refers to the “last layer fabricated” and “bottom” refers to the “first layer fabricated”. Hence, the term “first electrode” used interchangeably with the “first transparent electrode” refers to the first electrode fabricated on a transparent substrate and the term “second electrode” used interchangeably with the “second transparent electrode” refers to the last electrode fabricated in a solar cell device, farthest from the transparent substrate. Furthermore, the solar cells of the present disclosure are illuminated through the polymeric concentrators and therefore the illumination side can be the bottom side of the solar cell—when the illumination is through the transparent substrate or the illumination side can be the top side of the solar cell—when the illumination is through the second electrode, depending upon the placement of the polymeric concentrator.

As used herein, the term “bulk band gap” refers to the intrinsic band gap of a “bulk” material, i.e. it is a basic property of a semiconductor or insulator. As used herein, the term “quantum-confined band gap” refers to an effective (changed) band gap that can result when a material is structured on a length scale smaller than its bulk exciton Bohr radius, for example, by making nanoparticles out of a material. When a material is structured on this scale, the band gap is “tuned” to higher energy. Colloidal quantum dots are an example of a material that has a quantum-confined band gap. The band gap of a colloidal quantum dot depends on the size of the colloidal quantum dot (larger quantum dots have smaller band gaps). The band gap of a quantum-confined material can never be smaller than the band gap of its corresponding bulk material. All of the solar cell materials mentioned in the application are bulk materials except for colloidal quantum dots. The ability to tune the band gap by changing the size of the nanoparticle (to match the solar spectrum, e.g.) is one of the main advantages of using colloidal quantum dots as solar cell materials. Hence, as used herein, the term “band gap of CQD” is used interchangeably with “band gap energy of CQD” and refers to the quantum-confined band gap energy.

Disclosed herein are solar cell devices, concentrators for solar cells, and methods of making them. The solar cell device of the present disclosure includes a transparent substrate, a solar cell fabricated over the transparent substrate, and a polymeric concentrator including a concentrating lens with a planar surface, with the concentrating lens being in optical alignment with the solar cell, such that the concentrating lens provides a uniform illumination over an entire surface of the solar cell.

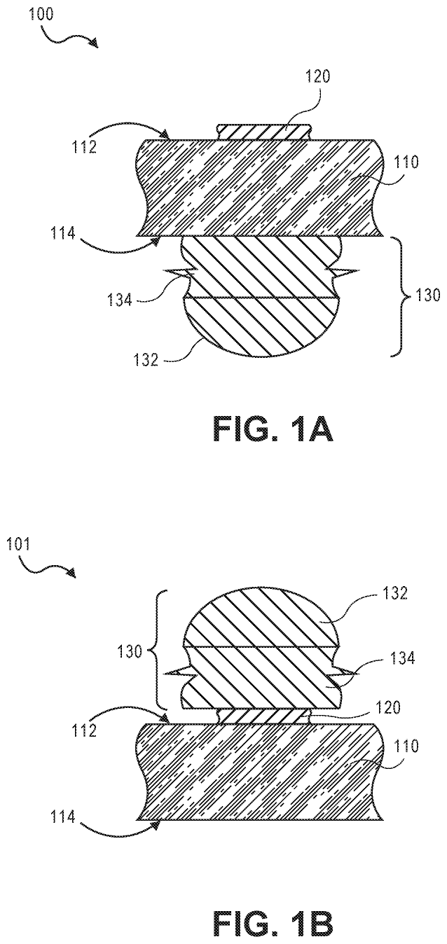

FIG. 1A schematically illustrates a cross-sectional view of a portion of an exemplary solar cell device 100, in accordance with various embodiment of the present disclosure. As shown in FIG. 1A, the solar cell device 100 includes a transparent substrate 110, a solar cell 120 fabricated over the transparent substrate 110, and a polymeric concentrator 130—layers are not shown to scale. In an embodiment, the transparent substrate 110 has a first surface 112 and a second surface 114, with the second surface 114 being opposite to the first surface 112. The solar cell 120 includes a first electrode (not shown) disposed over the first surface 112 of the transparent substrate 110 and an active layer (not shown) disposed in between and in contact with the first electrode (not shown) and a second electrode (not shown), with the second electrode being farthest away from the transparent substrate 110. The polymeric concentrator 130 of the present disclosure is a plano-lens including a concentrating lens 132 with a planar surface 134. In an embodiment, as shown in FIG. 1A, the transparent substrate 110 is disposed in between and in contact with the first electrode (not shown) of the solar cell 120 and the planar surface 134 of the polymeric concentrator 130, such that the concentrating lens 132 provides a uniform illumination through the transparent substrate 110 over an entire surface of the solar cell 120.

In another embodiment, FIG. 1B schematically illustrates a cross-sectional view of a portion of another exemplary solar cell device 101, where the solar cell 120 is disposed in between and in contact with the transparent substrate 110 and the planar surface 134 of the polymeric concentrator 130, such that the concentrating lens 132 provides a uniform illumination through the second electrode (not shown) over an entire surface of the solar cell 120.

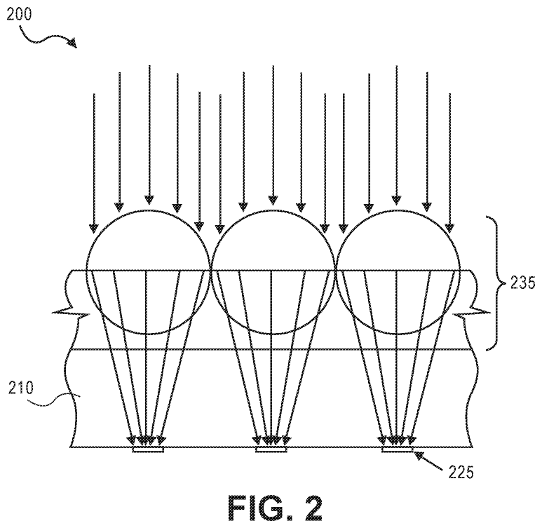

FIG. 2 schematically illustrates a cross-sectional view of another exemplary solar cell device 200, in accordance with various embodiment of the present disclosure. As shown in FIG. 2, the solar cell device 200 includes an array 225 of solar cell pixels, an array 235 of polymeric concentrators, and a transparent substrate 210 disposed in between and in contact with each solar cell pixel of the array 225 of solar cell pixels and the array 235 of polymeric concentrators, such that each concentrator provides a substantial uniform illumination over an entire surface of each solar cell pixel. In another embodiment (not shown), the array 235 of polymeric concentrators may be disposed over the array 225 of solar cell pixels, such that each solar cell pixel of the array 225 of solar cell pixels is disposed in between and in contact with the transparent substrate 210 and a polymeric concentrator of the array 235 of polymeric concentrators.

In an embodiment, the solar cell is a non-solution-processed-based solar cell. Non-solution-processed solar cells include crystalline, multicrystalline, polycrystalline semiconductor-based solar cells, and an amorphous silicon-based cell. Exemplary materials for these non-solution-processed solar cells include, but are not limited to silicon (Si), gallium arsenide (GaAs), and cadmium telluride (CdTe). In another embodiment, the solar cell is a solution-processed solar cell. Suitable examples of solution-processed solar cells include, but are not limited to a CQD solar cell, an organic solar cell, a perovskite solar cell, a dye-sensitized solar cell, a CIGS solar cell, a CZTS/Se solar cell, or a hybrid of these solar cell types. Types of CQD solar cells include but are not limited to depleted heterojunction CQD solar cells, Schottky junction CQD solar cells, quantum junction CQD solar cells, graded doping CQD solar cells, quantum funnel cells, multijunction CQD solar cells and the like.

Each solar cell 120 as shown in FIG. 1 and each solar cell pixel of the array 225 of solar cell pixels, as shown in FIG. 2 may include an active layer disposed in between a first transparent electrode and a second electrode. The active layer may include colloidal quantum dots (CQD), organic electronic materials, perovskites, dye sensitized porous material, or a mixture thereof.

In an embodiment, the active layer includes CQDs and the solar cell may further include an n-type conductive layer disposed in between and in contact the first transparent electrode and the active layer. The solar cell may also include a buffer layer sandwiched between the active layer and the second electrode. In some embodiments, the buffer layer is part of the second electrode.

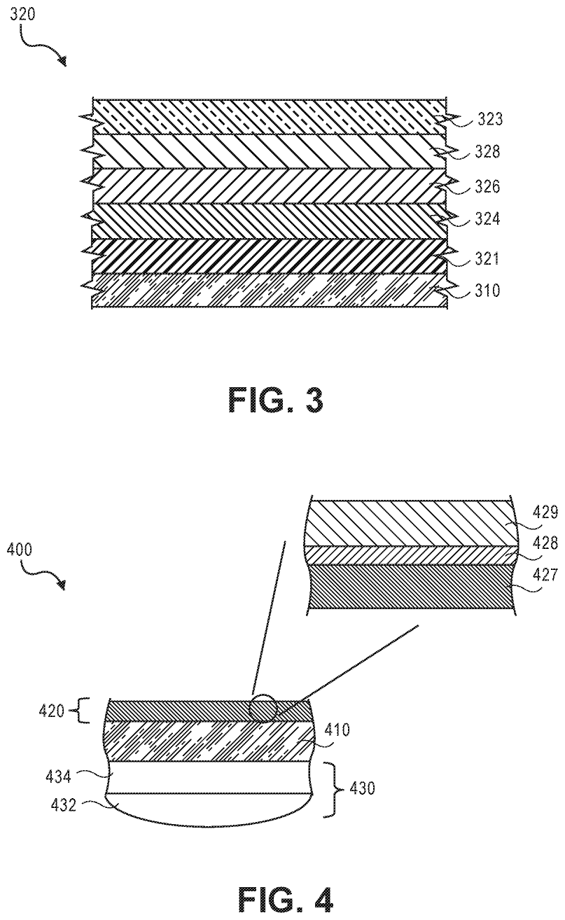

FIG. 3 schematic illustrates a cross-sectional view of an exemplary PbS CQD solar cell 320, including CQD in the active layer. As shown in FIG. 3, the CQD solar cell 320 includes a first transparent electrode 321 disposed over the first surface of the transparent substrate 310 and an n-type conductive layer 324 disposed over the first transparent electrode 321. The CQD solar cell 320 also includes a p-type conductive layer 326 sandwiched between the n-type conductive layer 324 and a second electrode 323. The p-type conductive layer 326 may include at least one layer of colloidal quantum dots (CQD). The CQD solar cell 320 may further includes a buffer layer 328 disposed in between and in contact with the p-type conductive layer 326 and the second electrode 323.

The buffer layer 328 as shown in FIG. 3, is sometimes considered part of the second electrode 323. A person of ordinary skill in the art would know that there are many different types of layers that can be involved in a CQD solar cell, and the specific layer structure discussed here and shown in the FIG. 3 is just one example.

Any suitable material can be used for the transparent substrate. In an embodiment, the transparent substrate is a rigid glass substrate. In another embodiment, the transparent substrate is a flexible transparent substrate, such as a flexible polymeric substrate or a flexible glass substrate. The flexible polymeric substrate may include any suitable transparent polymer, including, but not limited to a polyester, a polyimide, a polyamide, or a polymeric organosilicon compound. Suitable examples include, but are not limited to polyethylene terephthalate (PET), polyimide (PI), or polydimethylsiloxane (PDMS). The transparent substrate can have any suitable thickness, such as in the range of about 0.1-5 mm, or 0.5-4 mm, or 0.75-3.5 mm. The flexible transparent substrate can have any suitable thickness, such as in the range of about or 0.1-1.5 mm, or 0.15-1.2 mm, or 0.2-1 mm.

Suitable first transparent electrode materials include, but are not limited to indium tin oxide (ITO), fluorine-doped tin oxide (FTO), aluminum-doped zinc oxide (AZO), thin metallic silver, silver nanowires, graphene, poly(3,4-ethylenedioxythiophene) polystyrene sulfonate (PEDOT:PSS) or combinations of these or related materials. The first transparent electrode can have a thickness in the range of about 5-1000 nm, or 250-500 nm, or 20-50 nm.

Any suitable material may be used for the n-type conductive layer including, but not limited to titanium oxide (TiO₂), zinc oxide (ZnO), organic fullerenes, conjugated polymer donors, or n-type colloidal quantum dots. The n-type conductive layer can have a thickness in the range of about 10-10,000 nm, or 100-300 nm, or 20-50 nm, or 100-8000 nm, or 1000-5000 nm.

Any suitable materials may be used for the p-type conductive layer including, but not limited to colloidal quantum dots (CQDs), such as lead sulfide (PbS, bulk band gap energy of 0.41 eV) quantum dots, lead selenide quantum dots (PbSe, bulk band gap energy of 0.27 eV), or cadmium selenide quantum dots (CdSe, bulk band gap energy of 1.74 eV). The band gap energy of CQDs can be tuned from the near-infrared to the visible portion of the spectrum by varying the particle size. In an embodiment, the p-type conductive layer includes PbS CQDs having a particle size in the range of 2 to 10 nm. In another embodiment, the CQDs such as PbS CQDs are treated with at least one of tetrabutylammonium iodide (TBAI, or other organohalide salts), 1,2-ethanedithiol (EDT), benzene dithiol, mercaptopropionic acid (MPA), organic-inorganic hybrid perovskite, butylamine, pyridine, metal chalcogenide complexes (MCCs), molecular halides (Cl, Br, or I), halometallates (such as [PbI₃]—), pseudohalides (such as thiocyanates and azides), or combinations of these or other organic and inorganic ligands. The p-type conductive layer can have a thickness in the range of about 50-1000 nm, or 100-800 nm, or 200-500 nm.

Exemplary material for the buffer layer include molybdenum oxide (MoO₃). The buffer layer can have a thickness in the range of about 0-50 nm, or 5-40 nm, or 10-30 nm.

Suitable examples of the second electrode include, but are not limited to molybdenum trioxide (MoO₃) silver (Ag), gold (Au), platinum (Pt), nickel (Ni), titanium (Ti), and/or aluminum (Al). The second electrode can have a thickness in the range of about 5-1000 nm, or 100-300 nm, or can be made thicker if needed.

The polymeric concentrator can be fabricated using any suitable transparent material, including but not limited to polydimethylsiloxane, epoxy, spin-on-glass (SOG), or acrylic. In an embodiment, the polymeric concentrator is fabricated using a 3-D printed plastic mold.

In an embodiment, the CQD solar cell 320 comprises a structure Glass/ITO/TiO₂/PbS-CQD/MoO₃/Ag including ITO as a first transparent electrode 321 disposed over the first surface 312 of a glass layer as a transparent substrate 310 and TiO₂ layer as an n-type conductive layer 324 disposed over the ITO. The CQD solar cell 320 also includes a PbS CQD layer as a p-type conductive layer 326 sandwiched between TiO₂ layer and a silver layer as a second electrode 323. The CQD solar cell 320 may further includes MoO₃ layer as a buffer layer 328 disposed in between and in contact with the PbS CQD layer and the silver layer.

In an aspect, the solar cell device includes a multi-junction solar cell. FIG. 4 shows a schematic illustration of a cross-sectional view of an exemplary multi-junction solar cell device 400. The multi-junction solar cell device 400 includes a transparent substrate 410, a multi-junction solar cell 420 and a polymeric concentrator 430. The multi-junction solar cell 420 includes a visible junction 427 and an infrared junction 429 and a recombination layer 428 disposed in between and in contact with the visible junction 427 and the infrared junction 429. The visible junction 427 may include a transparent electrode (not shown) in contact with the transparent substrate 410. The infrared junction 429 may include a second electrode (not shown) on top of the infrared junction such that the infrared junction 429 is disposed in between and in contact with the recombination layer 428 on one side and the second electrode (not shown) on the opposite side. The transparent substrate 410 may be disposed in between and in contact with the visible junction 427 of the multi-junction solar cell 420 and a planar surface 434 of the polymeric concentrator 430. In such an arrangement, the concentrating lens 432 provides a uniform illumination over an entire surface of the solution-processed multi-junction solar cell 420.

Exemplary materials for the recombination layer(s) in the multijunction solar cells, include but are not limited to, metal oxides with graded work functions (MoO₃, ITO, AZO, etc.), thin metals (Ag, Al, etc.), conductive polymers (PEDOT:PSS), gold nanoparticles, etc. The recombination layer can have a thickness in the range of about 2-500 nm, or 10-300 nm, or 50-150 nm, or 5-20 nm.

The visible junction 427 may include any suitable solar cell, including, but not limited to a perovskite solar cell; an organic solar cell; a colloidal quantum dot solar cell; a crystalline, multicrystalline, or polycrystalline semiconductor-based cell; an amorphous silicon-based cell; a dye-sensitized solar cell; a CZTS/Se solar cell; a CIGS solar cell; or a hybrid thereof. The infrared junction 429 may include any suitable solar cell, including, but not limited to a colloidal quantum dot solar or a silicon solar cell.

In an embodiment of the multi-junction solar cell, the visible junction may include a perovskite solar cell and the infrared junction may include a CQD solar cell. In another embodiment of the multi-junction solar cell, both the visible junction and the infrared junction include a CQD solar cell.

In another embodiment of the multi-junction solar cell, there may be more than two junctions stacked on top of each other, with each junction going from bottom to top having a smaller band gap than the previous one, and so it absorbs and converts the photons that have energies greater than the band gap of that junction and transmits the photons with energies smaller than the band gap of that junction to the next layer

An exemplary perovskite-based visible junction may include a bottom transparent contact as the first electrode, such as, for example indium tin oxide, ITO, or fluorine-doped tin oxide, FTO; an electron transport layer such as TiO₂; a perovskite layer with a band gap in the range of 1.5 and 1.8 eV; and a hole transport layer such as (2,2′,7,7′-Tetrakis(N,N-di-p-methoxyphenylamine)-9,9′-spirobifluorene (spiro-OMeTAD), or similar.

Suitable examples of perovskites having a band gap in the range of 1.4-2.5 eV or 1.5-1.8 eV include, but are not limited to methylammonium lead iodide (CH₃NH₃PbI), methylammonium lead bromide (CH₃NH₃PbBr), methylammonium tin/lead iodide/bromide/chloride, cesium tin iodide/bromide/chloride, formadinium tin/lead iodide/bromide/chloride, related materials and alloys thereof.

An exemplary CQD infrared junction may include an electron transport layer/n-type wide band gap semiconductor, such as, for example TiO₂ or ZnO; CQDs with a band gap between 0.8 and 1.2 eV; and a second electrode of silver and/or gold.

Suitable examples of CQDs having a band gap in the range of 0.8 and 1.2 eV include, but are not limited to PbS and PbSe.

In an aspect, there is a method of making a solar cell. The method includes providing a transparent substrate having a first surface and a second surface, the second surface being opposite to the first surface and fabricating a solar cell on the first surface of the transparent substrate by solution processing. The method also includes providing a polymeric concentrator including a concentrating lens with a planar surface, and optically aligning the concentrating lens of the polymeric concentrator with the solar cell, such that the concentrating lens provides a uniform illumination over an entire surface of the solar cell. In one embodiment, the step of optically aligning the concentrating lens of the polymeric concentrator with the solar cell further comprises bonding the planar surface of the polymeric concentrator with the second surface of the transparent substrate, such that the concentrating lens provides a uniform illumination through the transparent substrate over an entire surface of the solar cell. In another embodiment, the step of optically aligning the concentrating lens of the polymeric concentrator with the solar cell further comprises bonding the planar surface of the polymeric concentrator with the second electrode of the solar cell, such that the concentrating lens provides a uniform illumination through the second electrode over an entire surface of the solar cell.

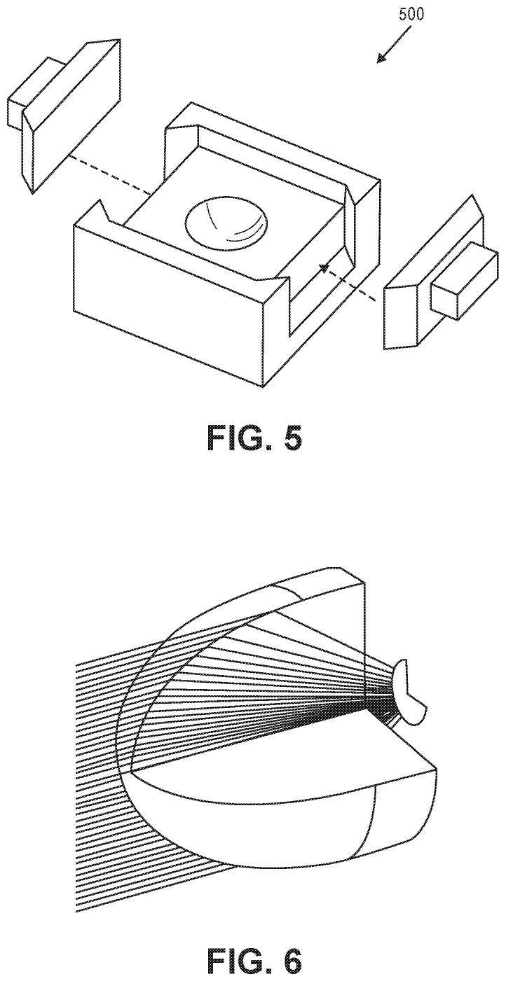

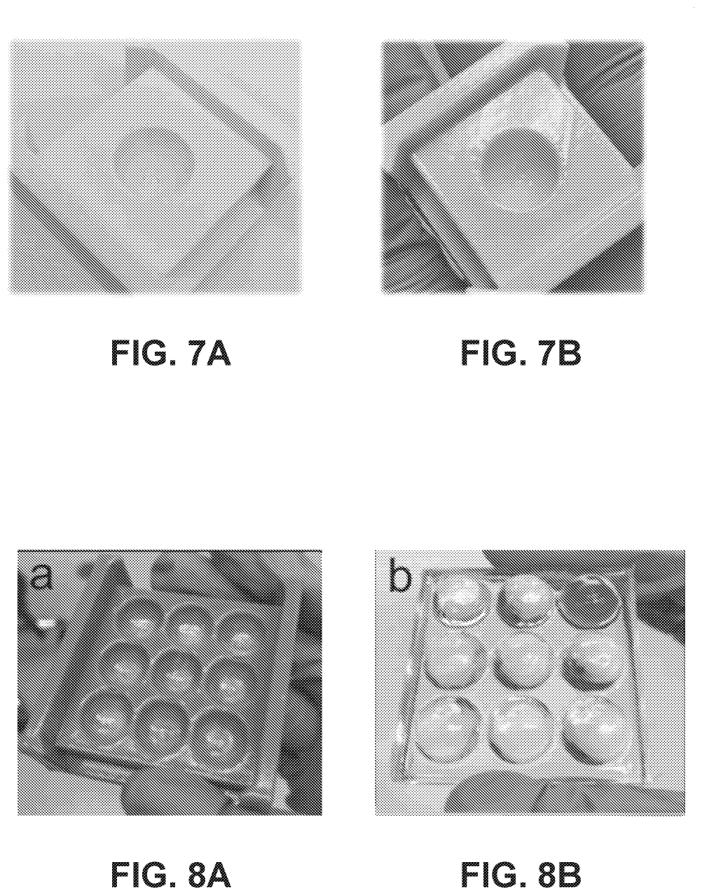

In one embodiment, the method of fabricating a polymeric concentrator includes first designing a computer-aided lens-mold (lens-mold CAD) 500, as shown in FIG. 5, by optical modelling, so as to uniformly illuminate the solar cell through the second surface of the substrate, as shown in FIG. 6, and adjust the lens focal point such that the light is focused at the plane containing the solar cell. The method also includes printing a three-dimensional lens mold, as shown in FIG. 7A, using the lens-mold CAD shown in FIG. 5 by additive manufacturing, followed by slurry polishing the lens-mold to create a smooth surface. FIGS. 7A and 7B shows an image of the lens-mold made using a 3-D printer before and after polishing respectively. The method further includes pouring a curable composition into the lens-mold and curing the curable composition to obtain a polymeric concentrator comprising a concentrating lens with a planar surface. FIG. 8A shows an image of an exemplary lens array-mold made using a 3-D printer. FIG. 8B shows an image of an array of concentrators made using the lens array-mold of FIG. 8A.

In an embodiment, the step of fabricating a solar cell on the first surface of the transparent substrate by solution processing includes fabricating an array of solar cell pixels on the first surface of the transparent substrate by solution processing and evaporation. In such embodiment, the step of providing a polymeric concentrator includes providing a flexible array of concentrators that allows collection of sunlight over the entire area that the solar cell device occupies while scaling down the illumination to the pixel size, thereby providing enhanced uniform illumination from each micro-concentrator over each of the solar cell pixels.

Any suitable material can be used for the curable composition including, but not limited to, polydimethylsiloxane, silicone, epoxy, spin-on-glass (SOG), acrylic, or other moldable, transparent materials.

The solar cell devices and the method of making them, as disclosed hereinabove provide numerous advantages over conventional solar cells such as a convenient and economical method to fabricate a polymeric concentrator that can be integrated with solution-processed solar cells, such as thin film PbS CQD solar cells. The use of additive manufacturing such as 3-D printing greatly reduces the cost of manufacturing of the concentrators. Furthermore, the use of concentrators in the solar cell devices of the present disclosure eliminates the need for the large-area film requirement of solution-processed solar cells, as the concentrators can scale down the illumination area and at the same time increase the intensity of the illumination. Furthermore, since power conversion efficiency (PCE) scales roughly logarithmically with illumination intensity, the use of concentrators in the solar cell devices of the present disclosure can provide improvement in PCE. Additionally, the concentrators can be integrated into the solar cells for one-component packaging as the polymeric concentrators can be bonded to any surface. Furthermore, the concentrators of the present disclosure provide dual function by not only harvesting sunlight from large areas and scaling the illumination down to solar cell pixel size, but also by acting as an encapsulation layer to protect the solar cells from environmental degradation, thereby removing another costly design element from the solar cell devices/systems.

Aspects of the present disclosure may be further understood by referring to the following examples. The examples are illustrative, and are not intended to be limiting embodiments thereof.

### EXAMPLES

### Materials

A colloidal solution of PbS quantum dots (PbS CQD), having quantum dot particle size of 3 nm and band gap of 1.3 eV, was synthesized as disclosed hereinbelow. Vinyl-terminated polydimethylsiloxane (PDMS) (Sylgard® 184) with curing agent was obtained from Sigma Aldrich.

### Preparation of PbS Quantum Dots (PbS CQD)

A solution of lead oleate was prepared by degassing a solution of lead oxide and oleic acid in octadecene (ODE) at 95° C. for 16 hours. The lead oleate solution was heated while connected to a Schlenk line and injected with a solution of hexamethyldisilathiane (TMS) in ODE at a temperature of about 120° C. The temperature can be varied in the range of 100-150° C. depending on the size of the CQDs one is aiming for. The solution was allowed to cool to room temperature and the nanoparticles were isolated by injecting acetone, followed by centrifuging, removing the supernatant, and redissolving the precipitate in toluene. The toluene solution was washed 1-4 times with methanol and finally the nanoparticles were redissolved in octane at a concentration of 50 mg/mL. It should be noted that there are many post-synthesis treatments that can be done on the nanoparticles that usually involve injecting solutions of ligand materials after the injection of the TMS precursor.

Additionally, PbS CQDs can be purchased commercially from many sources, such as for example “PbS core-type quantum dots, oleic acid coated, fluorescence λₑₘ 1000 nm, 10 mg/mL in toluene,” available from Sigma-Aldrich, that could be used to make solar cell films.

Preparation of Solution-Processed Solar Cells without Concentrating Lens (Concentrator)

FIG. 3 shows a schematic of a PbS CQD-based solar cell (PbS CQD solar cell) used as control and in Examples 1 and 2, consisting of an optically thick glass substrate, followed by indium tin oxide (ITO, the first electrode), TiO₂ (the n-type layer), PbS CQD film (the p-type layer), MoO₃ (buffer layer), and Ag (the second electrode).

The CQD solar cell devices using PbS CQDs with a band gap of 1.3 eV were fabricated on a commercial ITO-coated glass substrates with ITO thicknesses of 28 nm. The TiO₂ layer was also deposited using e-beam evaporation for precise thickness control, and a TiCl₄ solution treatment was applied afterwards. The PbS CQD layer was built up using a layer-by-layer solid state ligand exchange process. Two or three drops of oleic acid capped PbS CQD solution in octane at a concentration of 50 mg/mL per layer were deposited through a 0.22 μm pore filter and spin-casted on the substrate over the TiO₂ layer. 0.5% mercaptopropionic acid (MPA) in methanol was used to soak the film for 3 seconds to replace the oleic acid, then the film was dried by spin-casting. Lastly, the films were washed with methanol twice to remove the unbound ligands, completing the deposition of one CQD film layer. The total CQD film thickness was controlled through the acceleration, spin speed, spin time and number of layers and verified using profilometry measurements. The thickness of the CQD layers was approximately 300 nm. The second electrode was composed of a thin MoO₃ buffer layer and Ag, which were both deposited via e-beam evaporation.

The resulting solar cell on glass substrate: ITO/TiO₂/PbS-CQD/MoO₃/Ag had a layer thickness of approximately 28/200/300/30/200 nm. The arrays were fabricated by evaporating the second electrode (MoO₃ and Ag) through a shadow mask.

### Example 1: Preparation of Solution-Processed Solar Cells with Flexible Concentrating Spherical Lens

### Step 1A: Optical Modeling of the Spherical Lens Design

A concentrating spherical lens for use with the PbS CQD solar cells prepared as disclosed hereinabove was designed, as shown in FIG. 6 using a ray tracing software, OpticStudio available from Zemax and the lens design was optimized for standard PbS CQD solar cells active areas and thickness. The initial input parameters were an aperture diameter of the lens of 1.27 cm, a solar cell pixel diameter of 0.217 cm, and a glass substrate thickness of 1.1 mm. Considering the sunlight inputs from the back (first electrode) of the solar cell, the surface profile of the lens as well as its thickness were adjusted, to ensure that the output light spot size had the same size as the solar cell. The intensity of the concentrated light spot at the solar cell was also monitored during lens design optimization such that the lens design resulted in a nearly uniform intensity distribution similar to the spatial distribution of the unconcentrated sunlight. The nearly uniform intensity distribution of the concentrated light spot at the solar cell avoids open circuit voltage loss due to an equivalent parallel connection of sub-regions with uneven short circuit currents. A schematic of the concentrator in contact with the device is shown in FIGS. 1-2. Furthermore, the total thickness of the lens was minimized to reduce the absorption of light by PDMS, the material used to make the lens. This led to lenses with hemispherical or elliptical in shapes with edges almost perpendicular to the substrate. It was found that an aspherical design was necessary to eliminate the unevenness in intensity distribution, as shown in FIG. 6. The lens design was then used to create a computer aided design (CAD) of the lens-mold, as shown in FIG. 5 using SolidWorks or AutoCAD.

### Step 1B: Preparation of a Lens-Mold

The CAD of the lens-mold created in Step 1A was used to print a three-dimensional lens-mold in acrylonitirile-butadiene-sytrene copolymer (ABS) using a 3D printer, a uPrint SE Plus, by Stratasys (Eden Prairie, Minn.).

Due to the limited precision in the layer thickness of the 3D printer, the raw lens-mold had visible stairs and crevices, which are undesirable as these can lead to imperfect lens surface resulting in undesired scattering and degradation of the concentrated beam quality. The lens-mold surface quality was enhanced using a slurry polishing procedure, including first making an ABS/acetone slurry by mixing ABS powder (remnants from the 3D printing process) in acetone. The lens-mold was submerged in the ABS/acetone slurry in a closed container and at room temperature for 30 minutes, followed by air drying. The ABS/acetone slurry removed most of the surface roughness thereby resulting in a lens-mold with a smoother surface. This surface of the lens-mold surface was mechanically polished with wool Dremel heads to further refine the surface. FIGS. 7A and 7B shows images of as-is 3D printed lens-mold and after smoothing process.

### Step 1C: Preparation of Concentrating Spherical Lens

The lens-mold obtained in Step 1B was filled with a mixture of PDMS monomer and curing agent, Sylgard® 184 in a ratio of 10:1 monomer to curing agent and cured at a temperature of 80° C. for 1-20 hours to form a flexible PDMS concentrating spherical lens. The resulting flexible PDMS lens transmitted above 85% of the impingent light over a solar-relevant wavelength range of 400-1100 nm, as shown in FIG. 10.

The flexible PDMS concentrating spherical lens (concentrator) was characterized with optical measurements. The total transmission of the concentrator was measured in an integrating sphere, in the same configuration that is used for the solar cell, and also with a 0.217 cm diameter aperture to exclude the light hitting the planar part of the concentrator. For comparison purposes, transmission of a PDMS slab of the same thickness was also measured. As shown in FIG. 10, the PDMS lens has a transmission above 85% across the wavelength range of 400-1100 nm. However, the transmission measurement could still overestimate the actual amount of power received by the pixel because it does not rule out the light scattered out of the pixel area due to the uncorrected defects in the lens.

### Step 1D: Bonding of the PDMS Concentrating Spherical Lens to the Surface of the PbS CQD Solar Cell

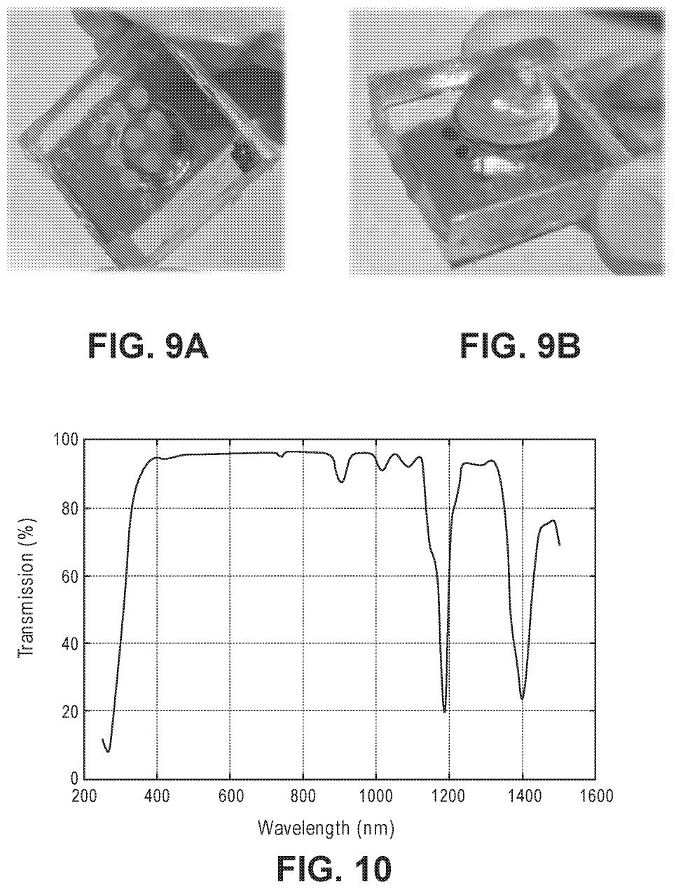

The second surface of the flexible PDMS lens was bonded to the PbS CQD solar cell array. The resulting flexible PDMS concentrating spherical lens was bonded to a CQD solar cell using a thin layer of uncured PDMS monomer and curing agent in a 10:1 ratio applied between the lens and the solar cell substrate, as shown in FIGS. 9A and 9B.

### Example 2: Preparation of Solution-Processed Solar Cells with Flexible Concentrating Conical Aspherical Lens

A procedure similar to Example 1 was used to make solution-processed solar cells, except that the flexible concentrating conical aspherical lens was designed and used instead of the spherical lens used in the Example 1.

### Photovoltaic Device Characterization

The performance of the integrated concentrator solar cells of Example 1 and 2 with concentrators were measured and compared with the control solar cell-equivalent non-concentrated CQD solar cells. Current-voltage measurements were done using a Keithley 2400 source meter with illumination provided by Sciencetech a solar simulator with an irradiance of 100 mWcm². The active area of the solar cell was illuminated through a circular aperture of 0.217 cm diameter to the front of each solar cell and the power source intensity was measured using a Thorlabs broadband power meter through the circular aperture. The different input power levels were achieved by adjusting the output of the solar simulator as well as testing with and without the lens. The current-voltage (I-V) curves are shown in FIG. 10. The measured short circuit current (I_{SC}), open circuit voltage (V_{OC}), fill factor (FF), and maximum power (P_{MAX}) results are summarized in Table 1.

TABLE 1

| | | | % | | % | | % | | % |
|---|---|---|---|---|---|---|---|---|---|
| | | | Change | | Change | | Change | | Change |
| | PbS | | V_{OC} wrt | | I_{SC} wrt | | PMAX | | FF wrt |
| | CQD | V_{OC} | to | I_{SC} | to | P_{MAX} | wrt to | Fill | to |
| | Solar cell | (V) | Control | (mA) | Control | (mW) | Control | Factor | Control |
| Control A | No lens | 0.415 | — | 0.421 | — | 0.053 | — | 30.5% | — |
| Example | Spherical | 0.487 | 17% | 1.481 | 252% | 0.179 | 238% | 24.8% | −19% |
| 1A | lens (0.5″ | | | | | | | | |
| | diameter) | | | | | | | | |
| Example | Conical | 0.473 | 14% | 0.900 | 114% | 0.106 | 100% | 24.8% | −19% |
| 2 | lens (0.5″ | | | | | | | | |
| | diameter) | | | | | | | | |

As shown in Table 1, both the spherical and conical lens concentrators provide an improvement in both short-circuit current and open-circuit voltage. It should be noted that the spherical lens concentrator performed better as compared to the conical lens concentrator in providing higher short-circuit current, as well as by increasing V_{OC} up to 3-4 kT.

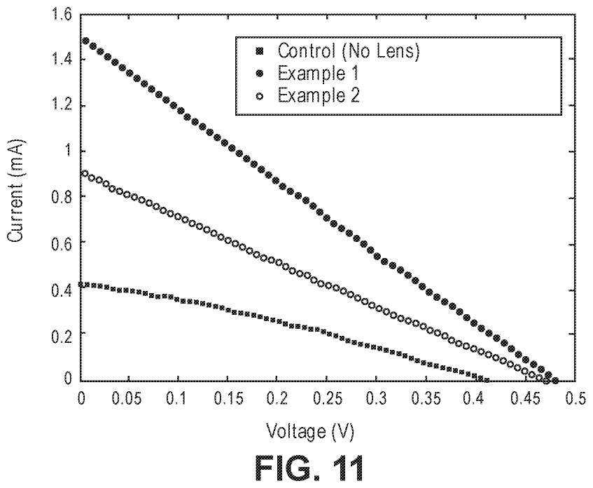

FIG. 11 shows an almost linear relationship between current and voltage. The I-V curves reveal a large contribution from various unideal factors which equivalently appear as large series resistance and parallel conductance, and are much more dominant at higher concentration level which seriously restricts the fill factor.

Table 1 shows a decrease in fill factor with the use of concentrator. Without being bound to a particular theory, it is believed that the fill factor drop could be due to three possible effects. 1) series resistance of the solar cell; 2) diminishing carrier extraction efficiency at higher concentration level at a constant forward bias; 3) Increased recombination at higher concentration level in the 1st quadrant of the I-V curve, with increased recombination at higher concentration being the most likely cause.

Another set of control solar cell and integrated concentrator solar cell of Example 1 with hemispherical lens was prepared and performance of the two solar cells were measured and compared and is summarized in Table 2. Table 2 shows that the concentrator is successful in harvesting solar power from an area much greater than the pixel itself, demonstrating a more than 11-fold increase in the actual short circuit current density, up to 145 mA/cm², as well as a more than 7-fold increase in the power density, reaching 21.1 mW/cm².

TABLE 2

| | Control B: | Example 1B: | |
|---|---|---|---|
| | Solar cell | Solar cell | n-fold Change |
| | without | with | (with concentrator/ |
| | concentrator | concentrator | without concentrator) |
| Pixel area (cm²) | 0.037 | 0.037 | |
| Aperture area (cm²) | — | 1.21 | |
| I_{SC} (mA/cm²) | 12.7 | 145 | 11.4 |
| V_{OC} (V) | 0.45 | 0.56 | 1.24 |
| FF | 0.47 | 0.26 | 0.55 |
| Power Density | 2.69 | 21.1 | 7.84 |
| (mW/cm²) | | | |

Thus, the Examples 1A, 1B, and 2 demonstrate a convenient and economical method to fabricate PDMS concentrators to be integrated with thin film PbS CQD solar cells. This method can potentially help overcome the difficulty in getting high-quality solar cell pixels with large areas, and allows for further exploitation of the scalability of CQD solar cells, as well as applications on flexible substrates. The present approach as disclosed hereinabove can increase the current density and power density of CQD solar cells up to 12 and 8 times, respectively, and possibly higher with refined concentrators. Although the concept of using flexible concentrators in a CQD solar cells is demonstrated in Examples 1 and 2 for a solar cell with a rigid glass substrate, any suitable flexible transparent substrate could be used with similar results.

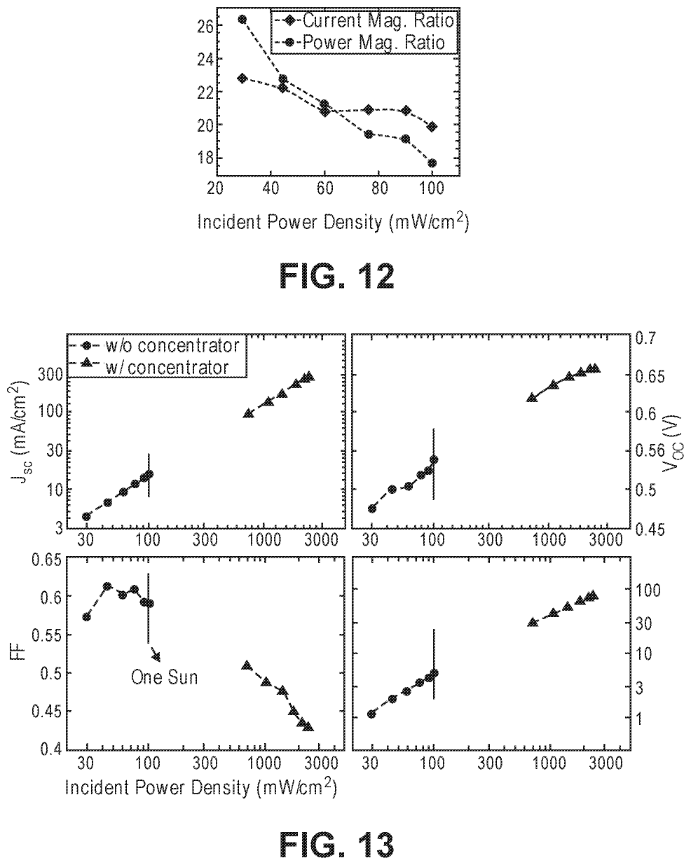

To further test the performance of the PDMS concentrators integrated with the thin film PbS CQD solar cells, current-voltage characteristics were measured under simulated solar illumination applied through a 1.25 cm diameter aperture. By adjusting the output of the solar simulator, different input power levels were achieved. Solar cells with hemispherical or elliptical concentrators (Examples 1B from above) were tested against solar cells without concentrators (Control B from above). As shown in FIG. 12, a significant increase in the short circuit current was observed after attaching the elliptical concentrator to the solar cell. The current magnification, which is the ratio of the integrated solar cell short circuit current with and without the concentrator, is stronger when the incident power density is below 1 sun (100 mW/cm²). It reached a value of 22.8 at an incident power of about 0.3 suns. The concentrated current density at 1 sun illumination was 302 mA/cm², 20 times that from the same solar cell without the concentrator. The power magnification ratio further indicated a 20 fold power enhancement with the concentrator with a maximum at an 0.3 suns illumination level.

FIG. 13 shows the PDMS elliptical concentrators integrated with the thin film PbS CQD solar cells produced up to a 4 kT increase in Voc, approaching a value of 0.67 V under a concentration ratio of 24×. The fill factor, however, decreased monotonically under concentration beyond 1 sun and, under most conditions, inhibited any potential for PCE improvement. Nonetheless, the output power increased monotonically with the input power density, exceeding 3.2 mW from a single pixel, equivalent to 850 W/m2 at 1 sun illumination with the concentrator, or under an effective concentrated power of 24 suns. The test results are summarized in FIG. 13. It is worth noting that the power magnification ratio under 0.3 suns is greater than 24 (the irradiance magnification), indicating an actual power conversion efficiency (“PCE”) improvement at low light levels. The magnification trend indicates that PCE improvements can be expected for illumination intensities below 0.3 suns under concentration as well. This is advantageous for realistic applications, since solar power in most deployment locations averages much less than 100 mW/cm2, and solar radiation levels can be under 0.3 suns for 30-40% of the daytime hours on sunny days and for even larger proportions under imperfect weather conditions.

The present disclosure has been described with reference to exemplary embodiments. Although a few embodiments have been shown and described, it will be appreciated by those skilled in the art that changes may be made in these embodiments without departing from the principles and spirit of preceding detailed description. It is intended that the present disclosure be construed as including all such modifications and alterations insofar as they come within the scope of the appended claims or the equivalents thereof.

What is claimed is:

1. A solar cell device comprising:
a) a transparent substrate;
b) a solar cell fabricated over the transparent substrate; and
c) a polymeric concentrator comprising a concentrating lens with a planar surface, wherein the concentrating lens is optically aligned with the solar cell such that the concentrating lens provides a uniform illumination over an entire surface of the solar cell.

2. The solar cell device of claim 1, wherein the transparent substrate comprises a first surface and a second surface, the second surface being opposite the first surface, and wherein the solar cell comprises a first electrode disposed over the first surface of the transparent substrate and an active layer disposed in between and in contact with the first electrode and a second electrode.

3. The solar cell device of claim 2, wherein the transparent substrate is disposed in between and in contact with the first electrode of the solar cell and the planar surface of the polymeric concentrator, such that the concentrating lens provides a uniform illumination through the transparent substrate over an entire surface of the solar cell.

4. The solar cell device of claim 2, wherein the solar cell is disposed in between and in contact with the transparent substrate and the planar surface of the polymeric concentrator, such that the concentrating lens provides a uniform illumination through the second electrode over an entire surface of the solar cell.

5. The solar cell device of claim 1, wherein the solar cell is a solution-processed solar cell.

6. The solar cell device of claim 1, wherein the solar cell comprises one or more of a perovskite solar cell; an organic solar cell; a colloidal quantum dot solar cell; a crystalline, multicrystalline, or polycrystalline semiconductor-based cell; an amorphous silicon-based cell; a dye-sensitized solar cell; a CZTS/Se solar cell; a CIGS solar cell; or a hybrid thereof.

7. The solar cell device of claim 1, wherein the active layer comprises one or more of colloidal quantum dots (CQD), organic electronic materials, perovskites, dye sensitized porous material, or a mixture thereof.

8. The solar cell device of claim 1, wherein the active layer comprises colloidal quantum dots (CQD).

9. The solar cell device of claim 7 further comprising an n-type conductive layer disposed in between and in contact the first transparent electrode and the active layer.

10. The solar cell device of claim 1, wherein each solar cell further comprises a buffer layer is disposed in between and in contact with the active layer and the second electrode.

11. The solar cell device of claim 1, wherein the polymeric concentrator comprises a spherical concentrating lens, a conical concentrating lens, an aspherical concentrating lens, or a Fresnel concentrating lens.

12. The solar cell device of claim 1, wherein the transparent substrate is a flexible polymeric substrate, or a flexible glass substrate.

13. The solar cell device of claim 9, wherein the flexible polymeric substrate comprises a polyester, a polyimide, a polymeric organosilicon compound or a polyimide.

14. The solar cell device of claim 1, wherein the polymeric concentrator is fabricated using a 3-D printed polymeric lens mold.

15. The solar cell device of claim 1 further comprises an array of solar cell pixels and an array of polymeric concentrators, where each concentrating lens of the array of polymeric concentrators is optically aligned with each solar cell pixel of the array of solar cell pixels, such that each concentrator provides a substantial uniform illumination over an entire surface of each solar cell pixel.

16. The solar cell device of claim 1, wherein the solar cell is a multi-junction solar cell comprising:
a) a visible junction including a first transparent electrode in contact with the first surface of the transparent substrate; and
b) a recombination layer disposed between and in contact with the visible junction and an infrared junction, wherein the infrared junction comprises a second electrode farthest from the transparent substrate.

17. The solar cell device of claim 11, wherein the visible junction comprises a perovskite solar cell; an organic solar cell; a colloidal quantum dot solar cell; a crystalline, multicrystalline, or polycrystalline semiconductor-based cell; an amorphous silicon-based cell; a dye-sensitized solar cell; a CZTS/Se solar cell; a CIGS solar cell; or a hybrid thereof; and
wherein the infrared solar cell comprises a colloidal quantum dot solar cell or a silicon solar cell; or a hybrid thereof.

18. A method of making a solar cell device comprising:
a) providing a transparent substrate having a first surface and a second surface, the second surface being opposite the first surface;
b) fabricating a solar cell on the first surface of the transparent substrate; and
c) providing a polymeric concentrator comprising a concentrating lens with a planar surface;
d) optically aligning the concentrating lens of the polymeric concentrator with the solar cell, such that the concentrating lens provides a uniform illumination over an entire surface of the solar cell.

19. The method of claim 18, wherein the step of optically aligning the concentrating lens of the polymeric concentrator with the solar cell further comprises bonding the planar surface of the polymeric concentrator with the second surface of the transparent substrate, such that the concentrating lens provides a uniform illumination through the transparent substrate over an entire surface of the solar cell.

20. The method of claim 18, wherein the step of optically aligning the concentrating lens of the polymeric concentrator with the solar cell further comprises bonding the planar surface of the polymeric concentrator with the second electrode of the solar cell, such that the concentrating lens provides a uniform illumination through the second electrode over an entire surface of the solar cell.

21. The method of claim 18, wherein the step of fabricating a solar cell on the first surface of the transparent substrate comprises fabricating a solar cell by solution processing.

22. The method of claim 18, wherein the step of providing a polymeric concentrator comprises:
a) designing a computer-aided lens-mold (lens-mold CAD) by optical modelling to uniformly illuminate the solar cell through the second surface of the substrate;
b) printing a three-dimensional lens mold using the lens-mold CAD by additive manufacturing;
c) slurry polishing the lens-mold to create a smooth surface;
d) pouring a curable composition into the lens-mold; and
e) curing the curable composition to obtain a polymeric concentrator comprising a concentrating lens with a planar surface.

23. The method of claim 22, wherein the curable composition comprises a mixture of a polydimethylsiloxane monomer and a curing agent.

24. The method of claim 22, wherein the curable composition comprises polydimethylsiloxane, silicone, epoxy, spin-on-glass (SOG), acrylic, or other moldable, transparent materials.
